(19) United States
(12) Patent Application Publication
(10) Pub. No.: US 2009/0122572 A1
(43) Pub. Date: May 14, 2009

(54) Apparatus configured to provide functional and aesthetic lighting from a fan

(75) Inventors: Erik R. Page, Winters, CA (US); Hideki Kawata, Richmond, CA (US)

Correspondence Address: PARK, VAUGHAN & FLEMING LLP, 2820 FIFTH STREET, DAVIS, CA, 95618-7759, US

(73) Assignee: The Regents of the University of California, Oakland, CA (US)

(21) Appl. No.: 12/291,254

(22) Filed: Nov. 7, 2008

Related U.S. Application Data
(60) Provisional application No. 60/986,498, filed on Nov. 8, 2007.

(51) Int. Cl. H01L 33/00; F21V 21/30

(52) U.S. Cl. 362/555; 362/35

(57) ABSTRACT

One embodiment of the present invention provides an apparatus that is configured to provide direct and/or indirect and aesthetic lighting from a fan. The apparatus comprises: a motor; a motor housing; one or more fan blades rotating around the motor housing; and one or more stationary light-emitting diodes (LEDs) coupled to the motor housing. Note that the stationary LEDs are configured to direct light into the fan blades, thereby causing the fan blades to illuminate.

### RELATED APPLICATION

This application hereby claims priority under 35 U.S.C. §119 to U.S. Provisional Patent Application No. 60/986,498, filed on 8 Nov. 2007, entitled “LED Ceiling Fan with LED Lighting Kit,” by inventors Erik R. Page and Hideki Kawata having attorney docket number UC08-187-1PSP.

### BACKGROUND

1. Field of the Invention

The present invention relates to household fans. More specifically, the present invention relates to an apparatus for facilitating direct and/or indirect and aesthetic LED lighting from a ceiling fan.

2. Related Art

With ever-rising energy costs, and a renewed emphasis on energy efficiency, many people are looking to replace or retrofit their existing lighting systems (including overhead fans) with newer energy-efficient systems. In addition, many companies are exploring energy efficient lighting for new construction projects. Light-emitting diodes (LEDs) are a popular new choice for lighting because: they are more energy efficient than compact fluorescents (CFLs); when they are first turned on, they deliver virtually all of their light output within milliseconds; they are not prone to failure due to power cycling; and they are typically packaged in arrays of multiple LEDs which minimizes the effects of a failed LED.

While LEDs present a cost-effective and energy-efficient long-term solution, they do present some inherent challenges. For example, LEDs can direct a majority of their light in a narrow beam. Hence, if a person happens to view the light from a point directly in that beam, the light will appear much brighter and could possibly cause vision damage.

Furthermore, many LEDs can require thermal management; otherwise, overheating can cause a loss of light output and premature failure of the LEDs. Note that placement of thermal management systems can prove problematic when retrofitting existing systems with LED lights.

Hence, what is needed is an apparatus for providing energy-efficient lighting while addressing the challenges listed above.

### SUMMARY

One embodiment of the present invention provides an apparatus that is configured to provide direct and/or indirect as well as aesthetic lighting from a fan. The apparatus comprises: a motor; a motor housing; one or more fan blades rotating around the motor housing; and one or more stationary light sources coupled to the motor housing. Note that the stationary light sources are configured to direct light into the fan blades, thereby causing the fan blades to illuminate, thus providing lighting to areas of the fan that could not be illuminated in a practical manner because the rotation of the fan prohibited running wires to the blades.

In some embodiments of the present invention, the light sources are light-emitting diodes (LEDs).

In some embodiments of the present invention, the illumination of the blades provides enough light for general illumination of a space without the need for additional functional lighting.

In some embodiments of the present invention, the fan blades are comprised of a material that transmits light, and the edges of the fan blades are treated to enhance illumination of the edges of the fan blades. Note that this treatment can include: sanding, frosting, roughing, texturing, or any surface treatment that enhances illumination.

In some embodiments of the present invention, a design is created in the fan blades, and the design is illuminated by the light from the stationary LEDs that is transmitted through the fan blades. Note that the design could be created using many different techniques, such as: etching, cutting, routing, and burning.

In some embodiments of the present invention, the fan blades are comprised of a layer of optical fiber such that one end of an optical fiber is directed toward the stationary LEDs, and one end of the optical fiber is directed away from the plane of rotation. In these embodiments, the light can be directed approximately perpendicular to the plane of rotation (toward the ground if the fan is a ceiling fan).

In some embodiments of the present invention, the stationary LEDs are comprised of LEDs of two or more colors.

In some embodiments of the present invention, the apparatus further comprises a color-cycling mechanism that energizes specific LEDs of different colors in a cycle to achieve a desired color output. This color-cycling mechanism is configured to adjust at a speed at which the color-cycling mechanism cycles through the LEDs of different colors. Note that the speed may be zero so that the desired color output remains constant.

In some embodiments of the present invention, the apparatus further comprises a timing mechanism that controls illumination of the stationary LEDs according to a rotational speed of the fan blades to create an appearance of an image on a section of the plane of rotation that is occupied by the fan blades.

In some embodiments of the present invention, the apparatus further comprises a timing mechanism that controls illumination of the stationary LEDs according to a rotational speed of the fan blades to minimize strobe and flicker effects as the fan blades rotate around the stationary LEDs.

In some embodiments of the present invention, the apparatus comprises ribs on an inside edge of the fan blades adjacent to the stationary LEDs. Note that the ribs create a cooling effect for the stationary LEDs by directing an airflow across the stationary LEDs.

One embodiment of the present invention provides an apparatus that is configured to provide functional lighting from a fan, comprising a lighting assembly. In these embodiments, the light assembly comprises: one or more light-emitting diodes (LEDs) coupled to the lighting assembly such that the LEDs direct their light in a direction which is different from a desired direction of illumination; and a reflective housing around the LEDs that reflects the light from the LEDs in the desired direction of illumination.

In some embodiments of the present invention, the apparatus comprises a lens coupled to the reflective housing to diffuse light leaving the reflective housing.

In some embodiments of the present invention, the apparatus comprises a heat sink coupled to the LEDs to direct heat away from the LEDs.

Note that the heat sink is situated so that it is cooled by the fan.

### BRIEF DESCRIPTION OF THE FIGURES

The patent or application file contains at least one drawing executed in color. Copies of this patent or patent application publication with color drawing(s) will be provided by the Office upon request and payment of the necessary fee.

FIG. 1 illustrates a ceiling fan in accordance with an embodiment of the present invention.

FIG. 2 illustrates an expanded view of a ceiling fan in accordance with an embodiment of the present invention.

FIG. 3 illustrates the backside of the ceiling fan motor housing in accordance with an embodiment of the present invention.

FIG. 4 illustrates the stationary LED ring in accordance with an embodiment of the present invention.

FIG. 5 illustrates the ceiling fan with the stationary LEDs off and the fan off in accordance with an embodiment of the present invention.

FIG. 6 illustrates the ceiling fan with the stationary LEDs on and the fan off in accordance with an embodiment of the present invention.

FIG. 7 illustrates the transfer of light from the stationary LEDs to the fan blade edges in accordance with an embodiment of the present invention.

FIG. 8 illustrates a close-up view of the transfer of light from the stationary LEDs to the fan blade edges in accordance with an embodiment of the present invention.

FIG. 9 illustrates the ceiling fan with the stationary LEDs on and the fan on a medium speed in accordance with an embodiment of the present invention.

FIG. 10 illustrates the ceiling fan with the stationary LEDs on and the fan on a low speed in accordance with an embodiment of the present invention.

FIG. 11 illustrates the ceiling fan with an LED lighting kit in accordance with an embodiment of the present invention.

FIG. 12 illustrates an expanded view of the lighting kit in accordance with an embodiment of the present invention.

FIGS. 13-17 illustrate expanded views of an alternate LED lighting kits in accordance with an embodiment of the present invention.

FIG. 18 illustrates a detailed view of advanced lighting mechanisms and cooling features in accordance with an embodiment of the present invention.

### DETAILED DESCRIPTION

The following description is presented to enable any person skilled in the art to make and use the invention, and is provided in the context of a particular application and its requirements. Various modifications to the disclosed embodiments will be readily apparent to those skilled in the art, and the general principles defined herein may be applied to other embodiments and applications without departing from the spirit and scope of the present invention. Thus, the present invention is not limited to the embodiments shown, but is to be accorded the widest scope consistent with the principles and features disclosed herein.

### Overview

Embodiments of the present invention provide a ceiling fan with light-emitting diodes (LEDs), wherein the ceiling fan channels light to the fan blades and facilitates a wireless and seamless transfer of light. In some embodiments of the present invention, the fan also includes an LED lighting kit that can be executed in various designs utilizing various optical pathways.

Some features of embodiments of the present invention include:
A ceiling fan with LED technology that channels light wirelessly to the fan blades.
A ceiling fan with LED technology that utilizes optical fiber and/or clear acrylic or polycarbonate plastics to transfer light from a central source to the fan blades, offering a seamless form of light transfer and ambient illumination.
A ceiling fan with LED lighting kits that nearly eliminate the need for lamp replacements found in traditional ceiling fan lighting kits.
A ceiling fan that provides both: aesthetic fan blade illumination, and functional down-light components.
A retrofit LED lighting kit that can replace a variety of pre-existing non-LED lighting kits while reducing energy consumption and maintenance costs.
   Ceiling Fan with LEDs that Transfer Light Wirelessly to the Fan Blades

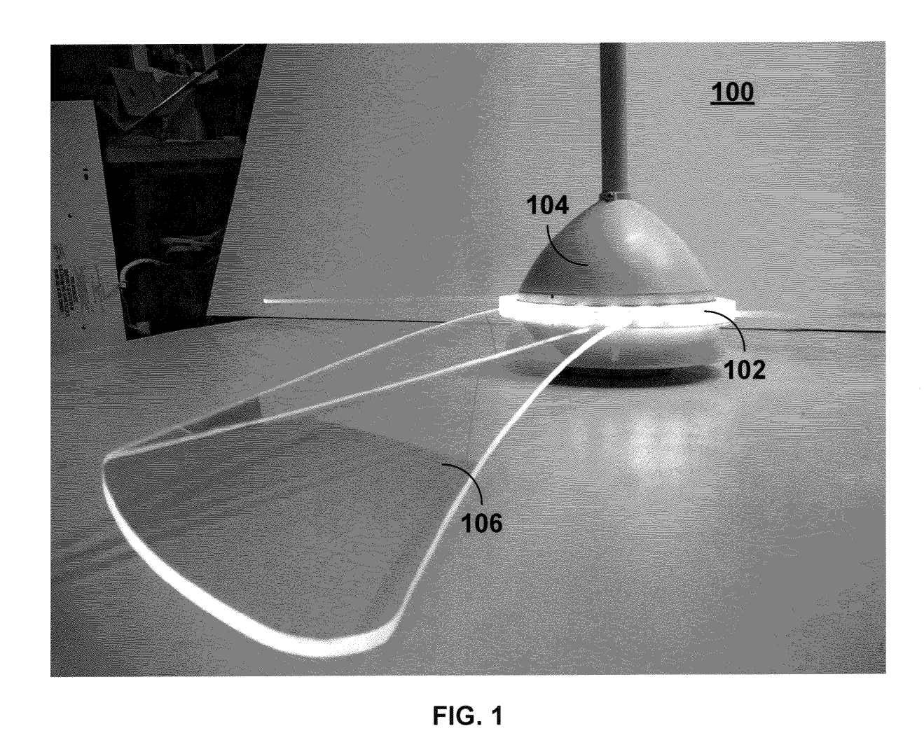

FIG. 1 illustrates a ceiling fan 100 in accordance with an embodiment of the present invention. As pictured in FIG. 1, LEDs 102 are arranged in a circular array around motor housing 104. LEDs 102 are mounted so that their light is directed outward in the plane of rotation so that the light is directed into the internal edge of fan blades 106. In the embodiment shown in FIG. 1, fan blades 106 are made of a clear acrylic. Note that other materials may be used that transmit light. In some embodiments of the present invention, fan blades 106 are made of layers of an opaque material with a layer of optical fiber sandwiched in the middle.

In some embodiments of the present invention, the surfaces of the fan blades 106 are frosted or sanded to transmit the light out of fan blades 106 and enhance the ambient lighting effect. Furthermore, in other embodiments of the present invention, logos or pictures may be etched into the fan blades so that the logos or pictures are illuminated by the light that is transmitted by fan blades 106.

In some embodiments of the present invention, the inside edge of fan blades 106, immediately adjacent to LEDs 102, is textured, ribbed, or comprises some structure to facilitate air flow over LEDs 102 to provide cooling for LEDs 102.

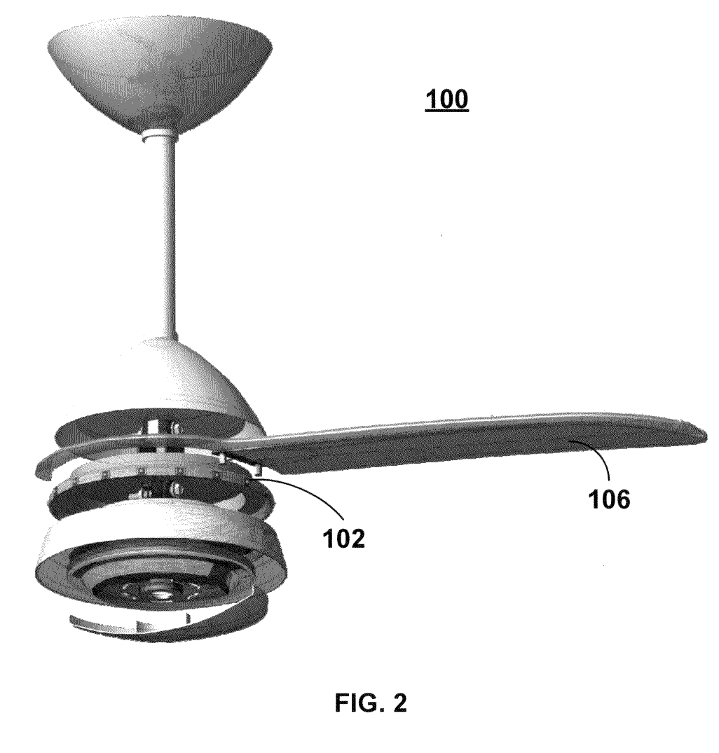

FIG. 2 illustrates an expanded view of ceiling fan 100 in accordance with an embodiment of the present invention. LEDs 102 are fixed in place on the support post and remain stationary. Fan blades 106 rotate around the array of LEDs 102, and the fiber optics and/or clear plastic of fan blades 106 channel the light to the edges of fan blades 106 and provide aesthetic and ambient illumination. The seamless connection between fan blades 106 and LEDs 102 prevents unwanted strobe and light flicker effects.

Note that in some embodiments of the present invention, multiple colored LEDs, such as RGB (red, green, and blue) can also be applied to this concept. With specific control of each colored diode in LEDs 102, color change and image projection is possible.

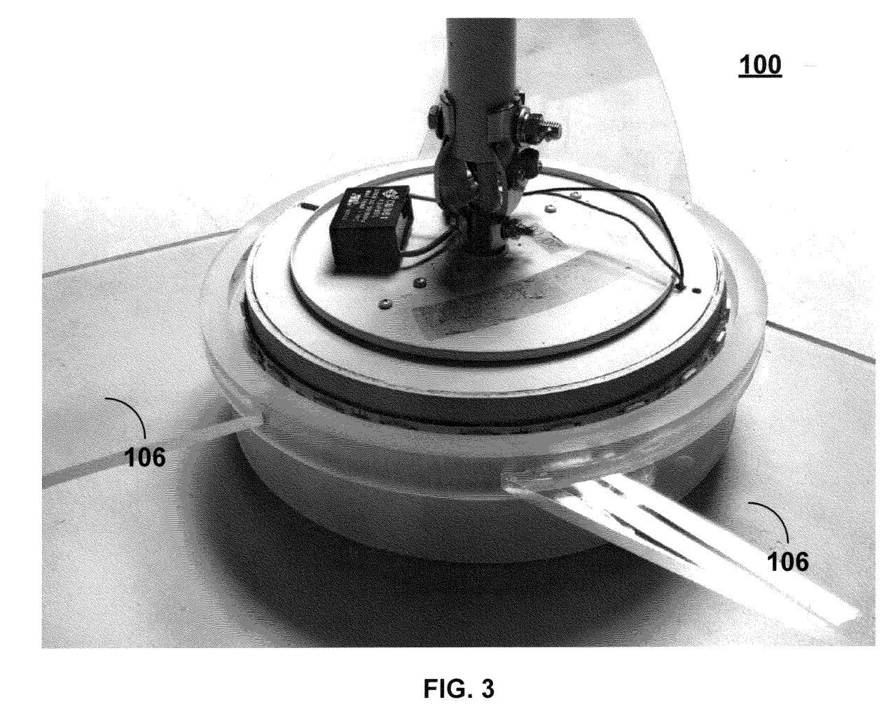

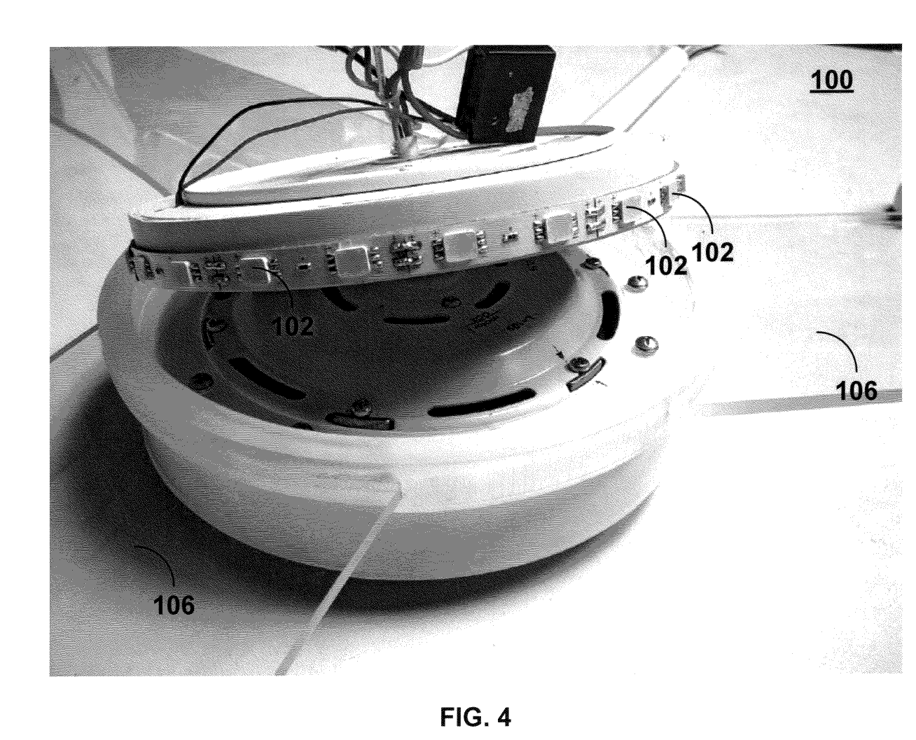

FIG. 3 illustrates the backside of the ceiling fan motor housing in accordance with an embodiment of the present invention, and FIG. 4 illustrates the stationary ring of LEDs 102 in accordance with an embodiment of the present invention. Note that the inside edge of fan blades 106 fits right up against LEDs 102. Furthermore, in some embodiments of the present invention, the inside of fan blades 106 is ribbed to provide air movement, and thus a cooling effect, on LEDs 102.

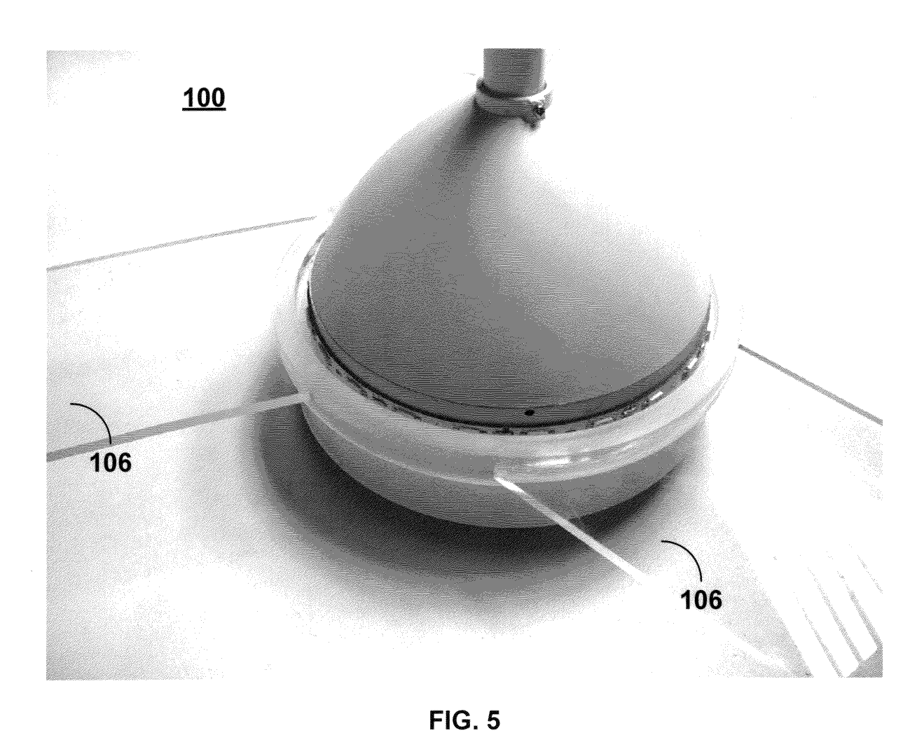

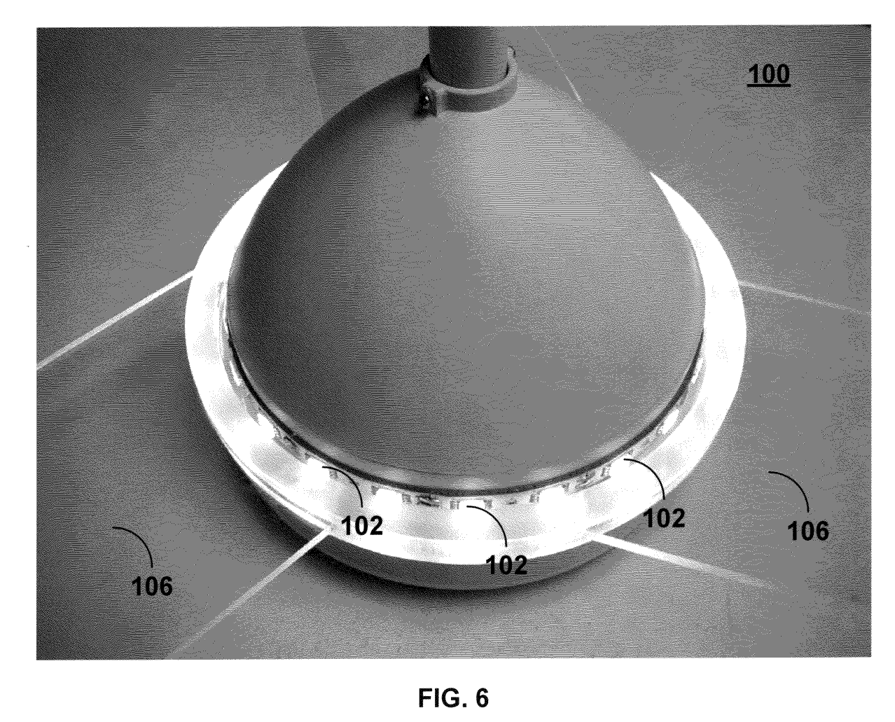

FIG. 5 illustrates ceiling fan 100 with the stationary LEDs 102 off and the fan off in accordance with an embodiment of the present invention, and FIG. 6 illustrates ceiling fan 100 with the stationary LEDs 102 on and the fan off in accordance with an embodiment of the present invention.

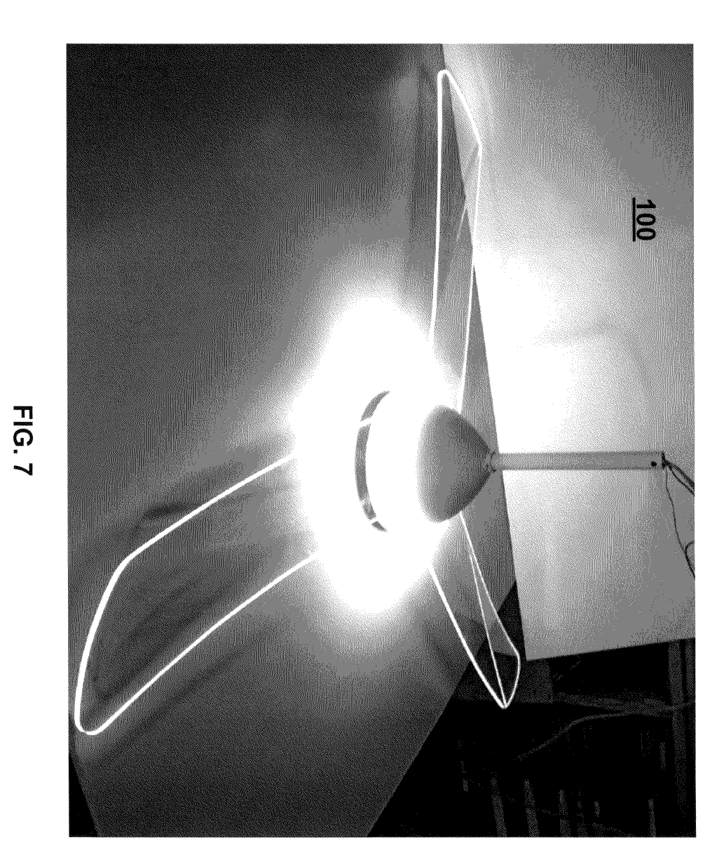

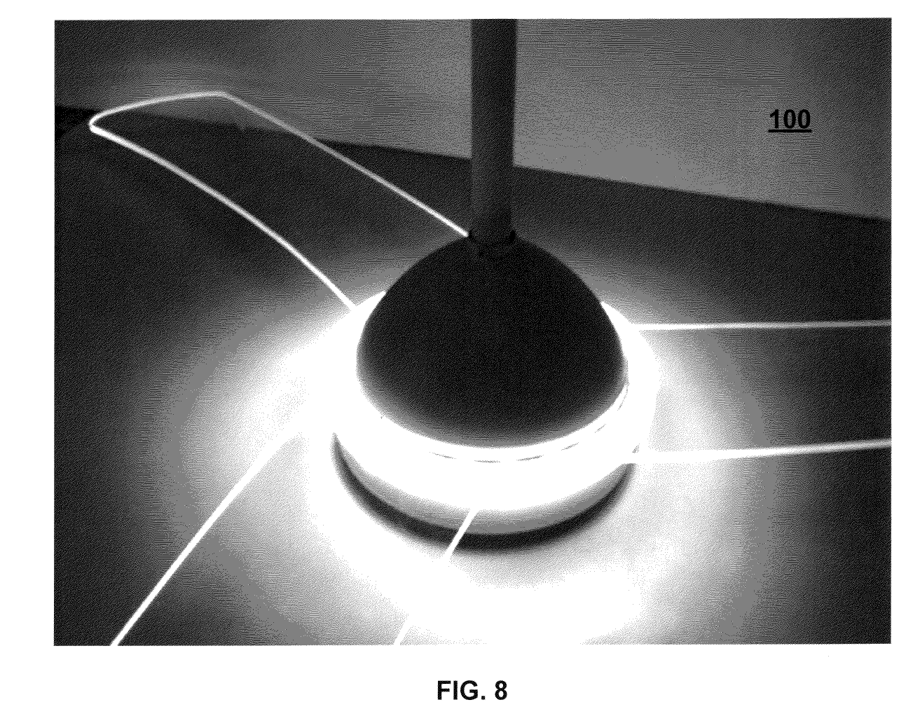

FIG. 7 illustrates the transfer of light from the stationary LEDs 102 to the edges of fan blades 106 in accordance with an embodiment of the present invention, and FIG. 8 illustrates a close-up view of the transfer of light from the stationary LEDs 102 to the edges of fan blades 106 in accordance with an embodiment of the present invention.

Note that the frosted edges of fan blades 106 enhance the lighting effect by reflecting the light out of fan blades 106.

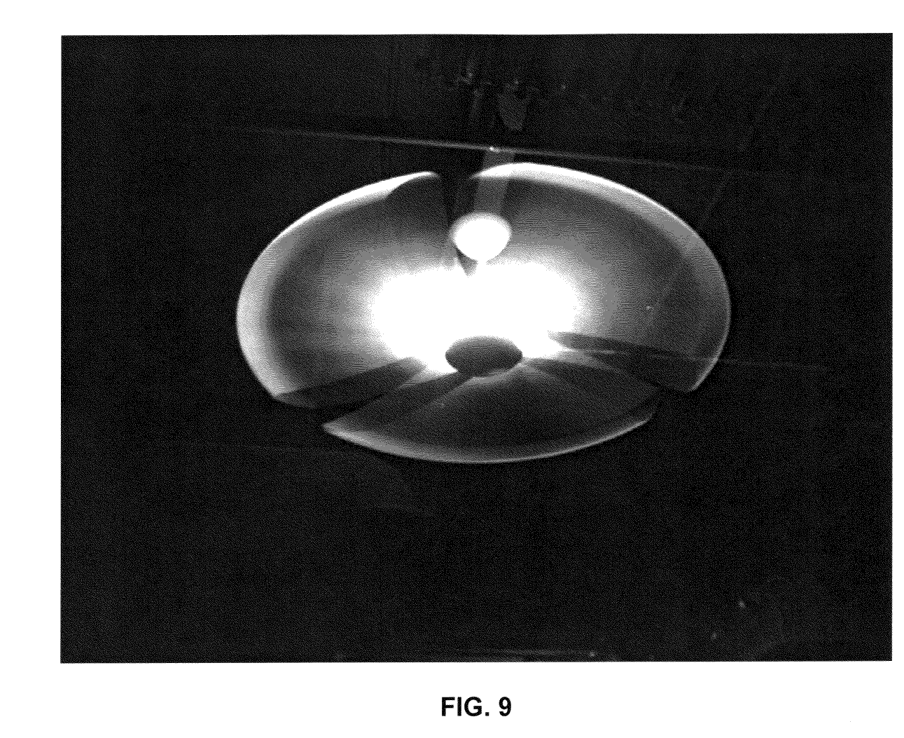

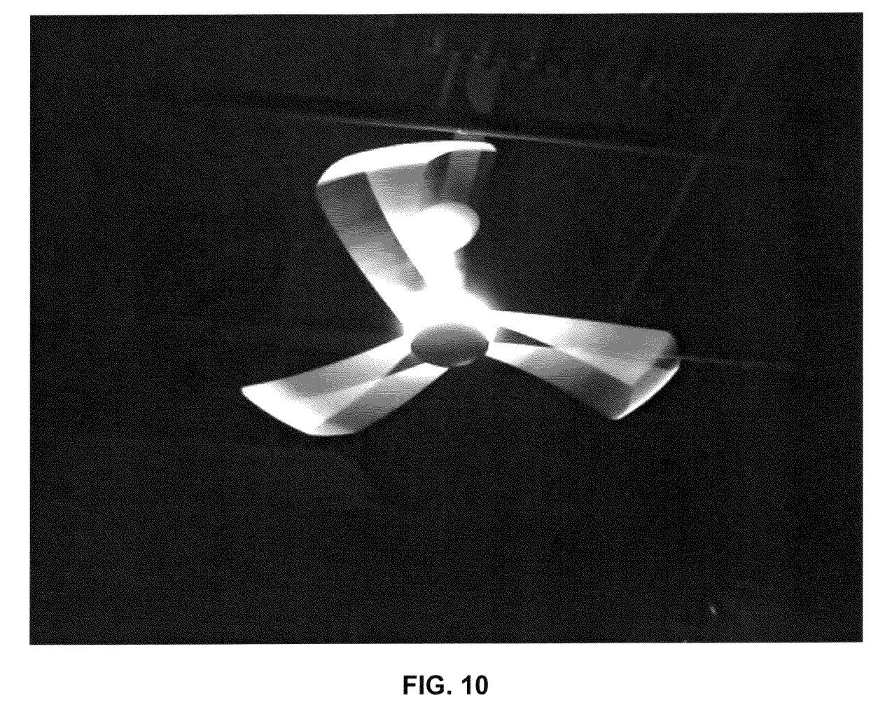

FIG. 9 illustrates the ceiling fan 100 with the stationary LEDs 102 on and the fan on a medium speed in accordance with an embodiment of the present invention, and FIG. 10 illustrates the ceiling fan 100 with the stationary LEDs 102 on and the fan on a low speed in accordance with an embodiment of the present invention.

### LED Lighting Kits

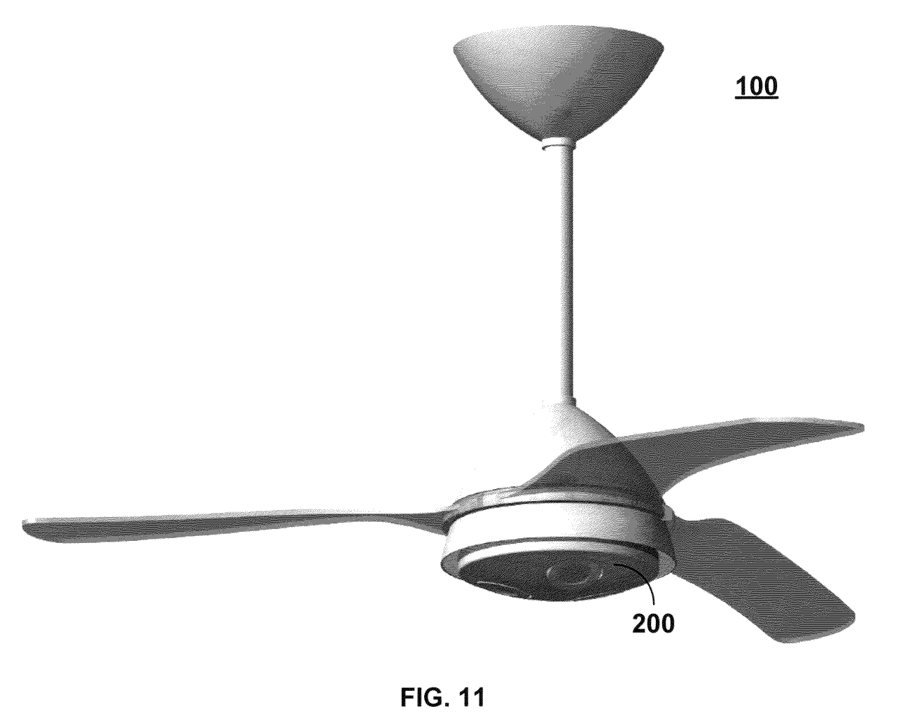

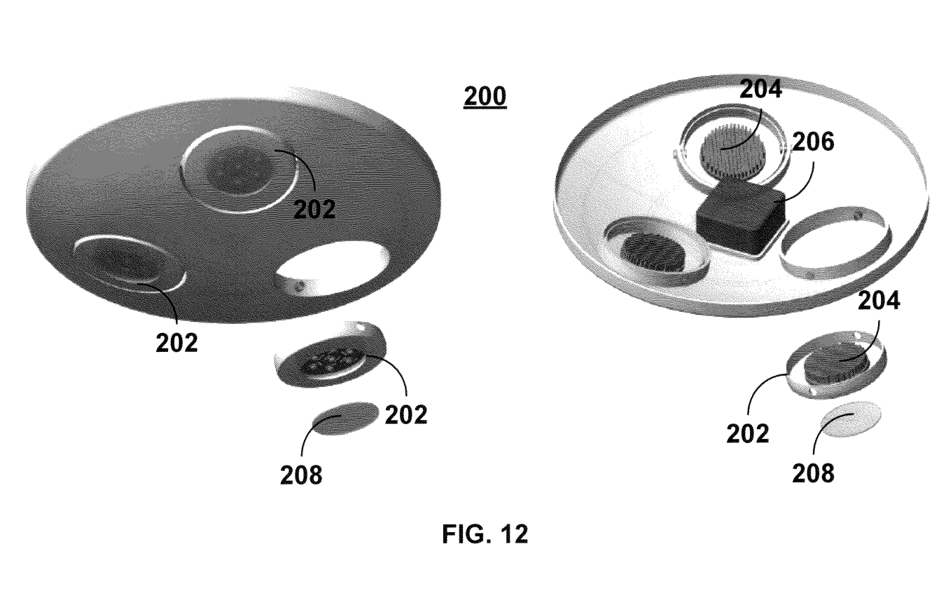

FIG. 11 illustrates the ceiling fan 100 with an LED lighting kit 200 in accordance with an embodiment of the present invention, and FIG. 12 illustrates an expanded view of lighting kit 200 in accordance with an embodiment of the present invention.

In one embodiment of the present invention, lighting kit 200 comprises three individual LED light units 202 (each holding an array of LEDs) that can be rotated and or pivoted to control the direction of light. Coupled behind each unit is a heat sink 204 (creating a path for thermal dissipation) and central driver unit 206. Note that heat sink 204 can include any type of heat sink, and is known to those skilled in the art. A diffusive lens or acrylic cover 208 is also attached to the exterior face of each unit to both minimize glare and offer protection to the LEDs. Such an approach can be applied to a variety of fan types, increasing both energy savings and overall performance.

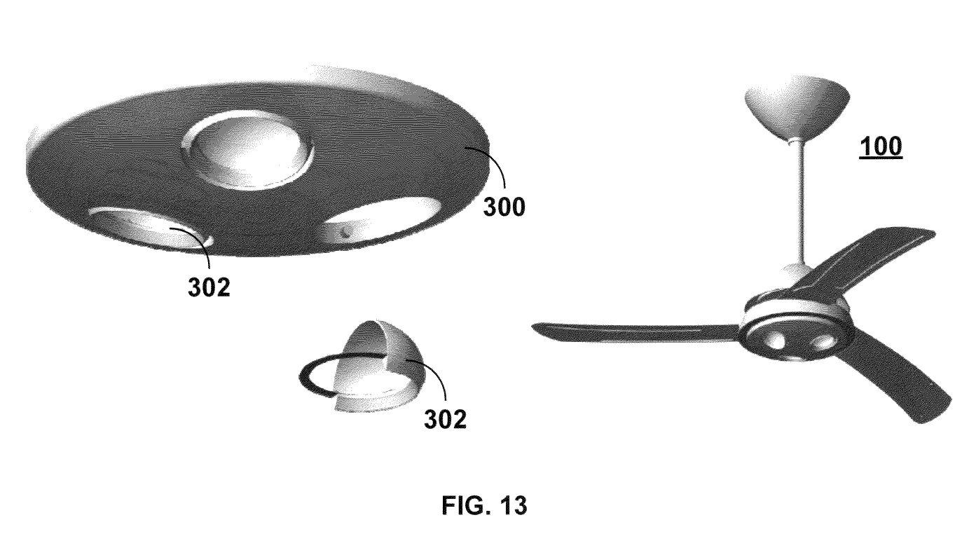

FIGS. 13-17 illustrate expanded views of alternate LED lighting kits in accordance with an embodiment of the present invention.

In the embodiment illustrated in FIG. 13, lighting kit 300 comprises three individual LED light units 302 (each holding a circular array of LEDs) that can be rotated and or pivoted to control the direction of light. Each light unit 302 is comprised of cast aluminum or a similar alloy, and the entire unit functions as a large heat sink. The LEDs are oriented facing upwards, and the light unit profile has been designed to redirect the light downwards to offer an indirect source for lighting. This approach minimizes the glare associated with LEDs and eliminates the possible need for an exterior diffusive lens or protective cap. Lighting kit 300 is attached to the bottom of the LED fan 100.

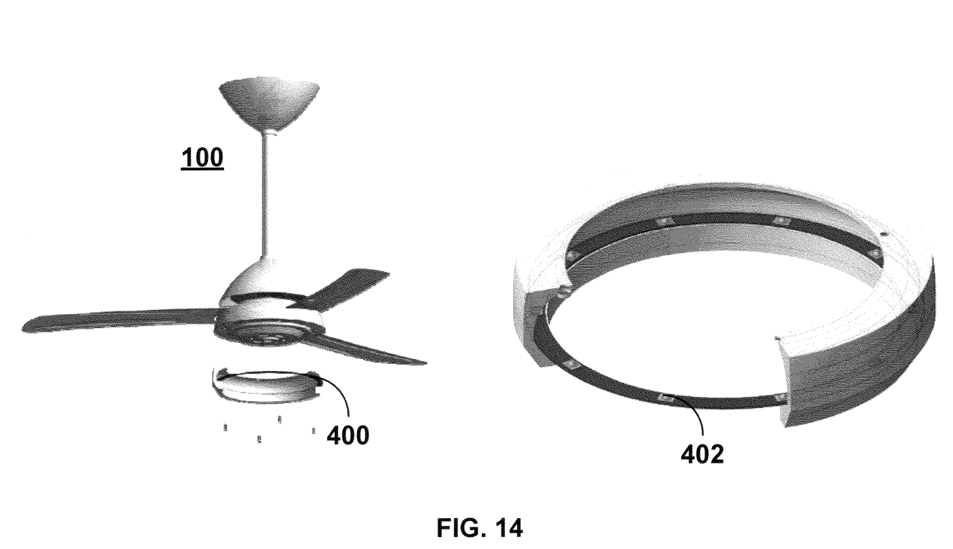

In the embodiment illustrated in FIG. 14, lighting kit 400 comprises a circular array of LEDs 402. The unit is comprised of cast aluminum or a similar alloy, and the entire unit functions as a large heat sink. The LEDs are oriented facing upwards, and the inner profile has been designed to redirect the light downwards to offer an indirect source of lighting. This approach minimizes the glare associated with LEDs and eliminates the possible need for an exterior diffusive lens or protective cap. Lighting kit 400 is attached to the bottom of the LED fan 100.

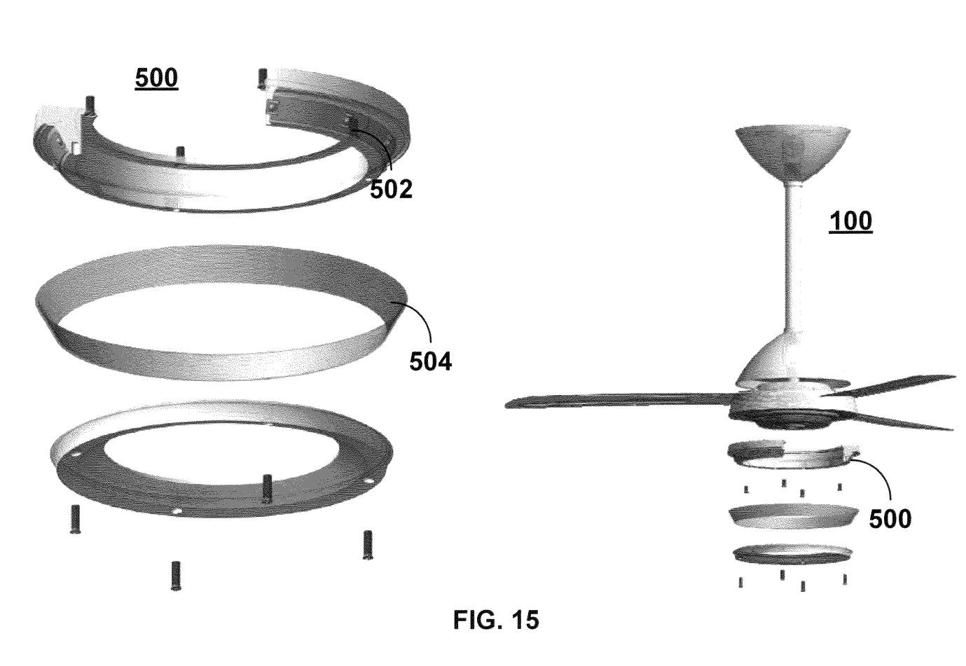

In the embodiment illustrated in FIG. 15, lighting kit 500 comprises a circular array of LEDs 502. The unit is comprised of cast aluminum or a similar alloy, and the entire unit functions as a large heat sink. The LEDs are oriented facing downwards at 30 degrees. The mounting angle can be variable. Covering the LEDs is a protective ring 504 that serves as a diffusive lens. Lighting kit 500 is attached to the bottom of the LED fan 100.

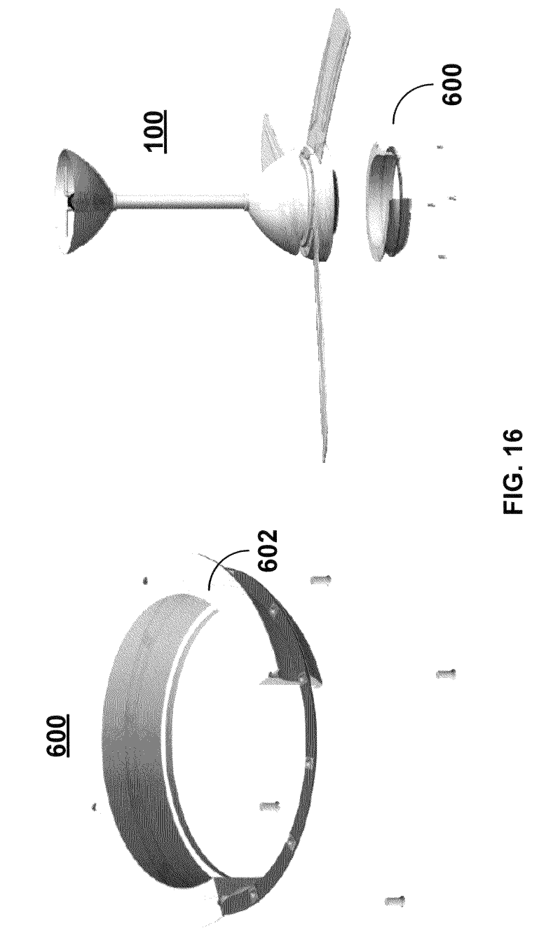

In the embodiment illustrated in FIG. 16, lighting kit 600 comprises a circular array of LEDs 602. The unit is comprised of aluminum or a similar alloy, and the entire unit functions as a heat sink. The LEDs are oriented facing upwards on the exterior rim of lighting kit 600. The exterior profile lining the inside edge of the LED 602 ring tapers upwards at a curve. This curvature was designed to redirect the flux downwards and achieve an indirect source of light with minimal glare. Lighting kit 600 is attached to the bottom of the LED fan 100.

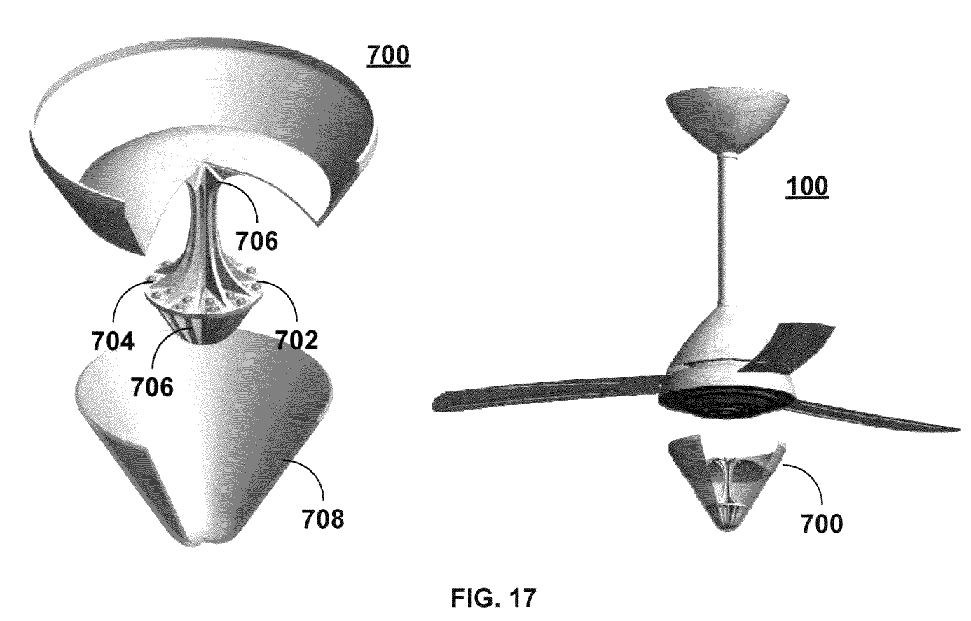

In the embodiment illustrated in FIG. 17, lighting kit 700 comprises a circular array of LEDs 702. The unit is comprised of aluminum or a similar alloy, and the entire unit functions as a heat sink. The LEDs are oriented facing upwards on a puck 704 that hangs down from center of the unit. Attached to puck 704 are fins 706 designed to draw heat away from the LEDs 702. The inner reflector geometry has been designed to direct the up light downwards, providing functional indirect illumination. Lighting kit 700 is attached to the bottom of the LED fan 100 and is finished with an acrylic/clear plastic cap 708 that also serves as a diffusive lens.

### Advanced Lighting Mechanisms and Cooling Features

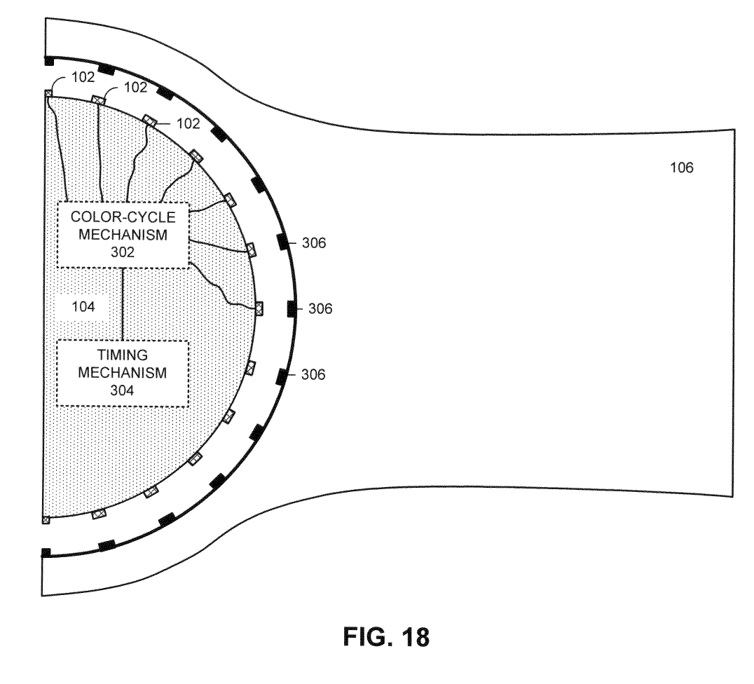

FIG. 18 illustrates a detailed view of advanced lighting mechanisms and cooling features in accordance with an embodiment of the present invention. As illustrated in FIG. 18, color-cycle mechanism 302 and timing mechanism 304 are attached to motor housing 104. Note that they could be attached inside of motor housing 104, or could be on the outside of motor housing 104, along with stationary LEDs 102.

Color-cycle mechanism is coupled to stationary LEDs 102 (not all couplings are shown), as well as to timing mechanism 304. In some embodiments of the present invention, color-cycle mechanism 302 and timing mechanism 304 are incorporated into one mechanism.

Stationary LEDs 102 can include LEDs of different colors, such as red, green, blue, and white, as well as multiple color LED assemblies wherein the assembly is capable of creating different colors. Color mechanism 302 controls which colors are illuminated at any given moment, and can control the speed at which fan 100 cycles through the colors.

In some embodiments of the present invention, timing mechanism 304 controls illumination of the stationary LEDs 102 according to a rotational speed of fan blades 106 to create an appearance of an image on a section of the plane of rotation that is occupied by fan blades 106. In addition, timing mechanism 304 controls illumination of the stationary LEDs 102 according to a rotational speed of fan blades 106 to minimize (or maximize if desired) strobe and flicker effects caused by fan blades 106 repeatedly blocking and revealing stationary LEDs 102.

In some embodiments of the present invention, the inside edge of fan blades 106 comprise ribs 306 adjacent to stationary LEDs 102. Note that ribs 306 create a cooling effect for stationary LEDs 102 by directing an airflow across stationary LEDs 102. Furthermore, ribs 306 can be attached to fan blades 106, or can be cut into fan blades 106.

### SUMMARY

Ceiling fan 100 and LED light kits 200-700 have several important advantages over traditional systems available on the market today. The nature of LED's and the amount of energy they require make the following features possible in ceiling fan 100:
Flexibility of optical control.
Increase in perceived brightness with less power consumption.
Energy cost savings (energy consumption can be reduced even more when used with smart sensor controls).
Retrofit opportunities.
Ambient lighting without flicker or strobe effects.
Image projection using the fan blades as the projection medium.

In order to utilize the LED light kits 200-700 as a possible retrofit, the variations in pre-existing lighting kit geometry and attachment mechanisms may require adapters. Most ceiling fans utilize a standard attachment thread. By designing a universal adapter part, nearly all LED ceiling fan lighting kits demonstrated above are valid solutions for retrofit.

The foregoing descriptions of embodiments of the present invention have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention. The scope of the present invention is defined by the appended claims.

What is claimed is:

1. An apparatus configured to provide functional and aesthetic lighting from a fan, comprising:
a motor;
a motor housing;
one or more fan blades rotating around the motor housing; and
one or more stationary light sources coupled to the motor housing, and wherein the stationary light sources are configured to direct light into the fan blades, thereby causing the fan blades to illuminate.

2. The apparatus of claim 1, wherein the stationary light sources are stationary light-emitting diodes (LEDs).

3. The apparatus of claim 2, wherein the fan blades are comprised of a material that transmits light, and wherein surfaces of the fan blades are treated to enhance illumination of the surfaces of the fan blades.

4. The apparatus of claim 3, wherein a design is created in the fan blades, and wherein the design is illuminated by the light from the stationary LEDs that is transmitted through the fan blades.

5. The apparatus of claim 2, wherein the fan blades are comprised of a layer of optical fiber such that one end of an optical fiber is directed toward the stationary LEDs, and one end of the optical fiber is directed away from the plane of rotation, whereby the light can be directed approximately perpendicular to the plane of rotation.

6. The apparatus of claim 2, wherein the stationary LEDs are comprised of LEDs of two or more colors.

7. The apparatus of claim 6, further comprising:
a color-cycling mechanism that energizes specific LEDs of different colors in a cycle to achieve a desired color output; and
wherein the color-cycle mechanism is configured to adjust a speed at which the color-cycling mechanism cycles through the LEDs of different colors, wherein the speed may be zero so that the desired color output remains constant.

8. The apparatus of claim 6, further comprising a timing mechanism that controls illumination of the stationary LEDs according to a rotational speed of the fan blades to create an appearance of an image on a section of the plane of rotation that is occupied by the fan blades.

9. The apparatus of claim 6, further comprising a timing mechanism that controls illumination of the stationary LEDs according to a rotational speed of the fan blades to minimize strobe and flicker effects as the fan blades rotate around the stationary LEDs.

10. The apparatus of claim 2, further comprising ribs on an inside edge of the fan blades adjacent to the stationary LEDs, wherein the ribs create a cooling effect for the stationary LEDs by directing an airflow across the stationary LEDs.

11. The apparatus of claim 1, further comprising a lighting assembly, wherein the lighting assembly comprises:
one or more light-emitting diodes (LEDs) coupled to the lighting assembly such that the LEDs direct their light in a direction which is different from a desired direction of illumination; and
a reflective housing around the LEDs that reflects the light from the LEDs in the desired direction of illumination.

12. The apparatus of claim 11, further comprising a lens coupled to the reflective housing that diffuses light leaving the reflective housing.

13. The apparatus of claim 11, further comprising a heat sink coupled to the LEDs configured to direct heat away from the LEDs, wherein the heat sink is situated so that it is cooled by the fan.
